(19) United States
(12) Patent Application Publication
(10) Pub. No.: US 2025/0321191 A1
(43) Pub. Date: Oct. 16, 2025

(54) ANALYSIS APPARATUS

(71) Applicant: Endress+Hauser SICK GmbH+Co. KG, Ottendorf-Okrilla (DE)

(72) Inventors: Peter FIMPEL, Konstanz (DE); Martin LOSKILL, Konstanz (DE)

(21) Appl. No.: 19/173,522

(22) Filed: Apr. 8, 2025

(30) Foreign Application Priority Data
Apr. 11, 2024 (EP) 24169574.1

(51) Int. Cl. G01N 21/65

(52) U.S. Cl. CPC G01N 21/65; G01N 2201/0612; G01N 2201/0635; G01N 2201/0636

(57) ABSTRACT

An analysis apparatus for analyzing a sample substance by means of Raman spectroscopy comprises a sample space for receiving the sample substance, a laser system for irradiating the sample substance located in the sample space with laser light, and a detection unit for generating a Raman spectrum using scattered light that emanates from the sample substance. The laser system has a laser unit comprising a light exit surface for the exit of a laser beam and a dispersing element that is arranged at a spacing from the light exit surface such that said dispersing element is acted on by the laser beam and transmits at least a portion of the laser light towards the light exit surface for a feedback. The sample space is arranged between the laser unit and the dispersing element and the detection unit is arranged such that it receives the scattered light emanating from the sample substance via the dispersing element.

The invention relates to an analysis apparatus for analyzing a sample substance by means of Raman spectroscopy, said analysis apparatus comprising a sample space for receiving the sample substance, a laser system for irradiating the sample substance located in the sample space with laser light, and a detection unit for generating a Raman spectrum using scattered light that emanates from the sample substance, wherein the laser system has a laser unit comprising a light exit surface for the exit of a laser beam and a dispersing element that is arranged at a spacing from the light exit surface such that said dispersing element is acted on by the laser beam and transmits at least a portion of the laser light back towards the light exit surface for a feedback.

Such apparatus are, for example, used for a contactless determination of the concentration of individual substances in substance mixtures. The sample substance can be a gas or a gas mixture. Corresponding gas analysis apparatus are, for example, required for the monitoring of industrial processes. However, liquids and solids can also be analyzed by means of Raman spectroscopy.

In Raman spectroscopy, the inelastic scattering of light on matter is investigated by spectrally evaluating the light scattered by a substance. The detected frequency shifts compared to the irradiated light are due to quantized rotational transitions, vibrational transitions and rotational-vibrational transitions and are characteristic of different types of molecules. Accordingly, Raman spectroscopy enables both a structural analysis of molecules and a qualitative and quantitative substance detection.

Raman signals are relatively weak so that a powerful laser unit must generally be provided. Furthermore, a high spectral purity of the excitation light is necessary to ensure a sufficient spectral resolution of the Raman signals. However, a corresponding laser system is associated with high costs and requires a lot of energy and installation space, which is in particular undesirable for industrially usable analysis apparatus.

The dispersing element is able to reduce the line width of the laser light and to transmit the laser light back to the laser output with the reduced line width. Between the light exit surface of the laser unit and the dispersing element, an external resonator is then formed that stabilizes the laser process and reduces the line width overall. The demands on the laser unit itself can be lowered by the external resonator. A further advantage of the external resonator is that a tuning of the wavelength of the laser light is possible, at least to a limited extent, by a position adjustment of the dispersing element.

An analysis apparatus that is based on Raman spectroscopy and that has a laser system comprising a laser unit and a dispersing element for forming an external resonator is disclosed in US 2022/0228911 A1.

The external resonator requires additional installation space that is often not available in measurement devices, for example. Furthermore, the dispersing element to be provided increases the manufacturing costs.

It is an object of the invention to provide an analysis apparatus of the aforementioned kind that has a high measurement sensitivity and a simple and compact design at the same time.

According to the invention, the sample space is arranged between the laser unit and the dispersing element and the detection unit is arranged such that it receives the scattered light emanating from the sample substance via the dispersing element.

The sample space is therefore located in the external resonator of the laser system. This saves installation space, on the one hand, and, on the other hand, ensures a particularly high irradiation power in the sample substance that results in a more powerful useful signal. Since the dispersing element furthermore serves both for the feedback the laser light and for the spectral separation of the Raman signals, a particularly compact design results. A dispersing element can in particular be saved compared to systems with a direct reception of the scattered light from the sample space.

The dispersing element is preferably a diffraction grating, for example a blazed grating. Diffraction gratings have a high spectral selectivity. Depending on the application, the diffraction grating can be designed as a transmission grating or as a reflection grating. The advantage of a transmission grating is its particularly high robustness and diffraction efficiency. A reflection grating, on the other hand, enables a mirror-free feedback arrangement. A prism could generally also be provided as a dispersing element instead of a diffraction grating or in addition to the diffraction grating.

The diffraction grating can be rotatable about an axis of rotation by means of a controllable drive. A rotation or tilting of the diffraction grating causes a change in the excitation wavelength and thus also in the wavelengths of the Raman signals. This can serve to increase the spectral resolution. A rotatable diffraction grating furthermore enables the use of a point detector for the spectral analysis of the scattered light since the spectral information is given by the angle of rotation of the diffraction grating. A sensor apparatus is preferably provided for detecting the current angle of rotation. Point detectors such as photomultipliers or photon counters are particularly sensitive and enable the detection of very small light signals. A specific embodiment of the invention provides that the detection unit has a silicon photomultiplier (SiPM). Furthermore, the detection unit can have an electronic signal filter module that is configured for a “lock-in” amplification or for a time-correlated single-photon detection.

The detection unit can generally have a spectrometer arrangement.

According to one embodiment of the invention, the diffraction grating is arranged and configured such that a diffracted light beam, in particular the light beam of the first order of diffraction, is transmitted from the diffraction grating back towards the light exit surface. Such an arrangement, also called a Littrow arrangement, can be implemented particularly easily.

A first mirror can be provided to reflect a light beam reflected or transmitted at the diffraction grating back to the diffraction grating again. Since the sample space is located within the cavity of the laser system, it is not necessary to decouple a useful beam. Thus, the radiation strength in the sample space can be increased by the back reflection of the beam of the zeroth order of diffraction at the first mirror.

A second mirror can also be provided to reflect a diffracted light beam back to the diffraction grating again to further increase the radiation strength in the sample space.

The laser unit is preferably a laser diode. Laser diodes are particularly compact and cost-effective. They are particularly suitable for a supplementing with an external resonator. The laser system can in particular be designed as an external cavity diode laser (ECDL).

The sample space can be partly or completely defined by a container, in particular a transparent cuvette. However, depending on the application, a channel that can be flowed through could also form the sample space.

According to a specific embodiment of the invention, the sample space is partly or completely formed by a cavity of a light-conducting hollow fiber element that preferably comprises microstructures. A so-called hollow-core-fiber can in particular be provided that is at least partly filled with the sample substance. This causes a further amplification of the Raman signal.

The detection unit can have a light receiver that is spatially resolving in at least one spatial direction. This enables a simultaneous detection of different Raman frequencies since the dispersing element ensures a directional splitting of the individual signal components. Thus, the Raman spectrum can be created particularly quickly and easily. The spatially resolving light receiver can be a CCD sensor, for example.

An imaging optics for imaging the dispersed light onto the spatially resolving light receiver can be arranged between the dispersing element and the detection unit in order to achieve an optimal separation of the individual Raman lines.

A further embodiment of the invention provides that a focusing lens for focusing the laser light in the sample space is arranged between the light exit surface and the sample space and a collimation lens for collimating the focused laser light is arranged between the sample space and the dispersing element. An intermediate focus is hereby produced in the sample space in which a particularly high light intensity is present.

A bandpass filter, whose transmission range is adapted to an emission wavelength of the laser unit, is arranged between the light exit surface and the sample space.

Such a cleaning filter or “clean-up” filter prevents interfering light emanating from the laser unit from being detected to an appreciable extent.

Further developments of the invention can also be seen from the dependent claims, from the description and from the enclosed drawings.

The invention will be explained in the following by way of example with reference to the schematic drawings.

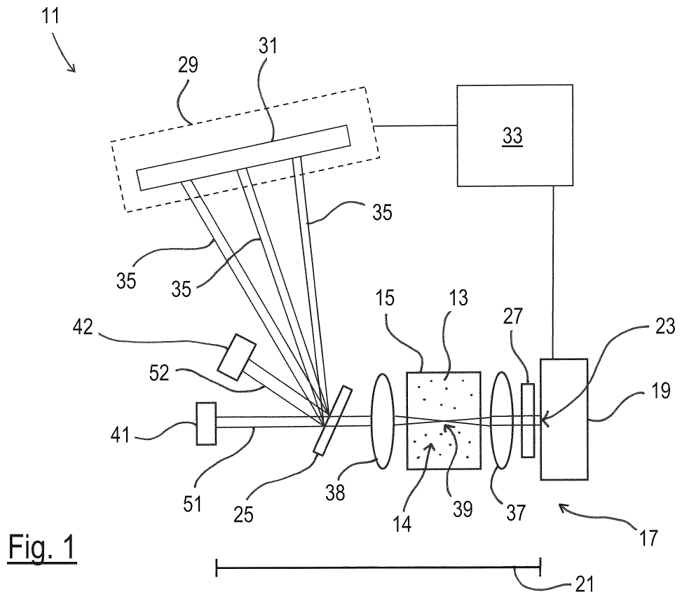

FIG. 1 is a simplified plan view of an analysis apparatus according to a first embodiment of the invention;

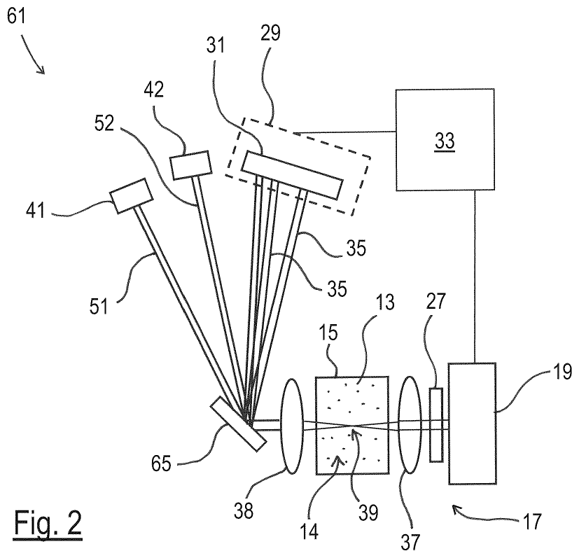

FIG. 2 shows an analysis apparatus according to a second embodiment of the invention;

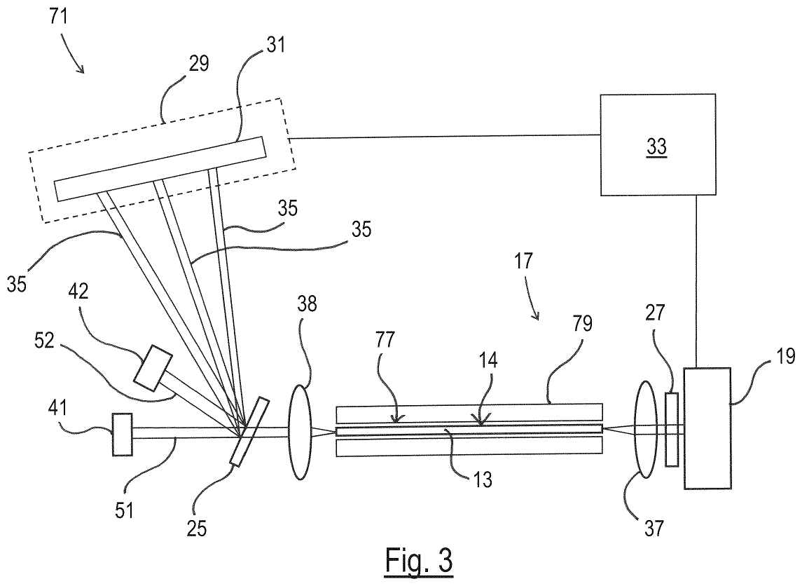

FIG. 3 shows an analysis apparatus according to a third embodiment of the invention; and

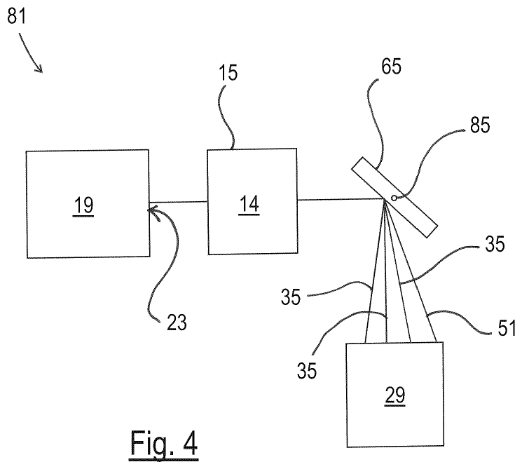

FIG. 4 shows an analysis apparatus according to a fourth embodiment of the invention.

The analysis apparatus 11 shown in FIG. 1 serves to analyze a gaseous or liquid sample substance 13 by means of Raman spectroscopy. The sample substance 13 is located in a sample space 14 that is here defined by a transparent container 15 such as a glass cuvette. A laser system 17 that comprises a laser unit 19 and an external resonator 21 is provided for irradiating the sample substance 13 located in the container 15 with laser light. The laser unit 19 is preferably a laser diode. The external resonator 21 is bounded by a light exit surface 23 of the laser unit 19 and at least by a first mirror 41. Furthermore, a diffraction grating 25 is provided in the external resonator 21. In the embodiment shown in FIG. 1, the diffraction grating 25 is a transmission grating. The first mirror 41 reflects the light beam 51 of the zeroth order of diffraction transmitted by the diffraction grating 25 back to the diffraction grating 25 again and into the sample space 14.

The diffraction grating 25 effects a spectrally selective feedback of laser light towards the light exit surface 23, which is accompanied by a reduction in the line width of the laser system 17. Specifically, the arrangement of the laser unit 19 and the diffraction grating 25 forms an external cavity laser diode (ECDL). To block interfering light, a bandpass filter 27 that is only permeable to light of a desired excitation wavelength is arranged in the region of the light exit surface 23.

The analysis apparatus 11 further has a detection unit 29 that comprises a spatially resolving light receiver 31 and that is adapted to generate a Raman spectrum using scattered light of the sample substance 13. The detection unit 29 is in signal connection with an electronic evaluation unit 33. The electronic evaluation unit 33 is configured to determine the concentration of at least one substance in the sample substance 13 based on the Raman spectrum and, preferably, to display said concentration on a display apparatus, not shown.

As shown, the detection unit 29 is arranged such that that light which is diffracted by the diffraction grating 25 and which corresponds to Raman signals 35 is incident on the spatially resolving light receiver 31. The scattered light emanating from the sample substance 13 is therefore not received directly, but rather via the diffraction grating 25. Thus, it is not necessary to equip the detection unit 29 with its own diffraction grating. The reception via the diffraction grating 25 is in particular possible in that the sample space 14 is arranged between the laser unit 19 and the diffraction grating 25, i.e. within the external resonator 21.

To increase the light intensity in the sample space 14, an intermediate focus 39 is produced in the sample space 14 by means of a focusing lens 37 and a collimation lens 38. The focusing lens 37 is located between the light exit surface 23 and the sample space 14, whereas the collimation lens 38 is arranged between the sample space 14 and the diffraction grating 25.

A further measure for increasing the light intensity in the sample space 14 comprises reflecting, by means of a second mirror, the light beam 52 of the first order of diffraction diffracted at the diffraction grating 25 back to the diffraction grating 25 again in order thus to effect a re-entry into the sample space 14.

FIG. 2 shows an alternative embodiment of an analysis apparatus 61 according to the invention that is substantially designed in the same way as the analysis apparatus 11 according to FIG. 1, but, in contrast thereto, has a diffraction grating 65 that is designed as a reflection grating and not as a transmission grating. Accordingly, the two mirrors 41, 42 are not arranged behind the diffraction grating 65, but laterally offset therefrom. Moreover, the reference signs used in FIG. 2 correspond to those of FIG. 1.

In FIG. 3, an embodiment of an analysis apparatus 71 according to the invention is shown that is substantially designed in the same way as the analysis apparatus 11 according to FIG. 1 and that in particular has a diffraction grating 25 designed as a transmission grating. Unlike the embodiment according to FIG. 1, the sample space 14 is, however, arranged in a cavity 77 of a light-conducting hollow fiber element 79. A separate container 15 for the sample substance 13 is not required in this variant.

A diffraction grating 65 designed as a reflection grating, as shown in FIG. 2, can also be positioned such that a Littrow arrangement is present. A corresponding analysis apparatus 81, in which no mirror is provided, is shown in FIG. 4. An axis of rotation 85 about which the diffraction grating 65 can be rotated by means of a drive, not shown, is furthermore shown in FIG. 4. Thus, the feedback can be influenced such that the excitation wavelength changes, whereby the Raman signals also change. A controllable drive for rotating or tilting the diffraction grating 25, 65 can moreover also be provided in the above-described embodiments.

Since the diffraction grating 25, 65 is used both for a spectral feedback in the laser system 17 and for a spectral splitting of the scattered light to be detected, the manufacturing costs can be kept low. The arrangement of the sample space 14 in the external resonator further allows a particularly compact design. A prism or another dispersing element could generally also be provided instead of a diffraction grating 25, 65.

### REFERENCE NUMERAL LIST

11 analysis apparatus
13 sample substance
14 sample space
15 container
17 laser system
19 laser unit
21 external resonator
23 light exit surface
25 diffraction grating
27 bandpass filter
29 detection unit
31 spatially resolving light receiver
33 electronic evaluation unit
35 Raman signal
37 focusing lens
38 collimation lens
39 intermediate focus
41 first mirror
42 second mirror
51 light beam of the zeroth order of diffraction
52 light beam of the first order of diffraction
61 analysis apparatus
65 diffraction grating
71 analysis apparatus
77 hollow space
79 hollow fiber element
81 analysis apparatus
85 axis of rotation

1. An analysis apparatus for analyzing a sample substance by means of Raman spectroscopy, said analysis apparatus comprising
a sample space for receiving the sample substance,
a laser system for irradiating the sample substance located in the sample space with laser light, and
a detection unit for generating a Raman spectrum using scattered light that emanates from the sample substance,
wherein the laser system has a laser unit comprising a light exit surface for the exit of a laser beam and a dispersing element that is arranged at a spacing from the light exit surface such that said dispersing element is acted on by the laser beam and transmits at least a portion of the laser light towards the light exit surface for a feedback,
wherein the sample space is arranged between the laser unit and the dispersing element and the detection unit is arranged such that it receives the scattered light emanating from the sample substance via the dispersing element.

2. The analysis apparatus according to claim 1,
wherein the dispersing element is a diffraction grating.

3. The analysis apparatus according to claim 2,
wherein the diffraction grating can be rotated about an axis of rotation by means of a controllable drive.

4. The analysis apparatus according to claim 2,
wherein the diffraction grating is arranged and formed such that a diffracted light beam is transmitted from the diffraction grating back towards the light exit surface.

5. The analysis apparatus according to claim 4,
wherein the diffracted light beam is the light beam of the first order of diffraction.

6. The analysis apparatus according to claim 2,
wherein a first mirror is provided to reflect a light beam reflected or transmitted at the diffraction grating back to the diffraction grating again.

7. The analysis apparatus according to claim 6,
wherein a second mirror is provided to reflect a diffracted light beam back to the diffraction grating again.

8. The analysis apparatus according to claim 1,
wherein the laser unit is a laser diode.

9. The analysis apparatus according to claim 1,
wherein the sample space is partly or completely defined by a container.

10. The analysis apparatus according to claim 9,
wherein the container is a transparent cuvette.

11. The analysis apparatus according to claim 1,
wherein the sample space is partly or completely formed by a cavity of a light-conducting hollow fiber element.

12. The analysis apparatus according to claim 1,
wherein the detection unit has a light receiver that is spatially resolving in at least one spatial direction.

13. The analysis apparatus according to claim 12,
wherein an imaging optics for imaging the dispersed light onto the spatially resolving light receiver is arranged between the dispersing element and the detection unit.

14. The analysis apparatus according to claim 1,
wherein a focusing lens for focusing the laser light in the sample space is arranged between the light exit surface and the sample space, and
a collimation lens for collimating the focused laser light is arranged between the sample space and the dispersing element.

15. The analysis apparatus according to claim 1,
wherein a bandpass filter, whose transmission range is adapted to an emission wavelength of the laser unit, is arranged between the light exit surface and the sample space.
